(19) United States
(12) Patent Application Publication
(10) Pub. No.: US 2024/0290803 A1
(43) Pub. Date: Aug. 29, 2024

(54) PACKAGING STRUCTURE AND ELECTRONIC DEVICE HAVING THE PACKAGING STRUCTURE

(71) Applicant: Rayprus Technology (Foshan) Co., Ltd., Foshan (CN)

(72) Inventors: KUAN-MING CHEN, New Taipei (TW); HSIANG-CHIEH YU, NewTaipei (TW); PANG-JUNG LIU, New Taipei (TW); YE-QUANG CHEN, Tu-Cheng (TW)

(21) Appl. No.: 18/216,733

(22) Filed: Jun. 30, 2023

(30) Foreign Application Priority Data
Feb. 24, 2023 (CN) 202310175337.5

(51) Int. Cl. H01L 27/146; H01S 3/02

(52) U.S. Cl. CPC H01L 27/14618; H01L 27/14627; H01L 27/14636; H01S 3/025

(57) ABSTRACT

A packaging structure includes a first transparent substrate including includes a first surface and a second surface, a second transparent substrate including a third surface facing the second surface, a support connecting the second surface and the third surface, an optical lens assembly on the third surface, a packaging assembly including includes a base on the first surface and electrodes, and an optical component. The second transparent substrate and the first transparent substrate are stacked in a first direction. A first cavity is defined by the support connecting the second transparent substrate and the first transparent substrate. A second cavity is defined by the base and the first transparent substrate. The optical component is received in the second cavity. The optical component and the optical lens assembly overlap in the first direction, the optical component is electrically connected to the electrodes and located between the first surface and the electrodes.

### FIELD

The subject matter herein generally relates to a packaging structure and an electronic device having the packaging structure.

### BACKGROUND

The optical packaging structure in the prior art generally includes a transparent substrate, and optical components and optical lens assemblies respectively disposed on two opposite surfaces of the transparent substrate. However, the optical components and the optical lens assemblies are prone to wear and scratches during manufacture, use or transportation, which affects the yield and service life of the packaging structure.

Therefore, there is room for improvement within the art.

### BRIEF DESCRIPTION OF THE DRAWINGS

Implementations of the present disclosure will now be described, by way of embodiments, with reference to the attached figures.

FIG. 1 is a cross-sectional view of a first embodiment of a packaging structure according to the present disclosure.

FIG. 2 is a cross-sectional view of a second embodiment of a packaging structure according to the present disclosure.

FIG. 3 is a flowchart of an embodiment of a method for manufacturing a packaging structure according to the present disclosure.

FIG. 4 is a diagram of an embodiment of an electronic device according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

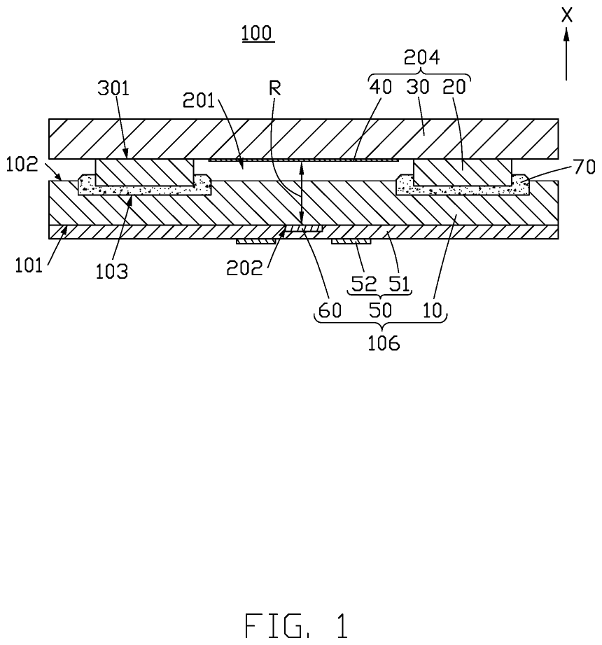

FIG. 1 illustrates a first embodiment of a packaging structure 100. The packaging structure 100 includes a first transparent substrate 10, a support 20, a second transparent substrate 30, an optical lens assembly 40, a packaging assembly 50, and an optical component 60.

The first transparent substrate 10 includes a first surface 101 and a second surface 102 facing away from the first surface 101. The first transparent substrate 10 and the second transparent substrate 30 are stacked in a first direction X. The second transparent substrate 30 includes a third surface 301 facing the first transparent substrate 10. Each of the first transparent substrate 10 and the second transparent substrate 30 may be respectively made of a material selected from epitaxial wafer, a transparent polymer material, glass, silicon, germanium, or a semiconductor compound. The support 20 is connected to the second surface 102 and the third surface 301. A first cavity 201 is defined by the first transparent substrate 10, the support 20, and the second transparent substrate 30. The support 20 may be made of a material selected from a semiconductor compound or a polymer material. The optical lens assembly 40 may be a Metalens, a diffractive element or a lens array. In at least one embodiment, the optical lens assembly 40 is a Metalens. The optical lens assembly 40 is received in the first cavity 201 and fixed on the third surface 301. The optical component 60 is fixed on the first surface 101 or separated from the first surface 101. The optical component 60 fixed on the first surface 101 can reduce a volume of the packaging structure 100 in the first direction X. The optical lens assembly 40 and the optical component 60 may overlap in the first direction X.

The packaging assembly 50 includes a base 51 and electrodes 52. The base 51 is fixed on the first surface 101. A second cavity 202 is defined by the base 51 and the first transparent substrate 10. The optical component 60 is received in the second cavity 202. The electrodes 52 are electrically connected to the optical component 60 and located on a side of the base 51 facing away from the first surface 101.

In at least one embodiment, the number of the electrodes 52 is at least two, a part of the electrodes 52 is at least one n-type electrode, and the other part of the electrodes 52 is at least one p-type electrode. Conducting circuits may be formed on the base 51. The n-type electrode 52 is electrically connected to a p-type conductive electrode layer of the optical component 60 through the base 51 with the conducting circuits, and the p-type electrode 52 is electrically connected to a n-type conductive electrode layer of the optical component 60 through the base 51 with the conducting circuits. When the electrodes 52 are connected to a power supply, the optical component 60 generates a light source or images a received light source.

In at least one embodiment, the baser 51 may be only an insulating substrate. The electrodes 52 extend through the base 51 to be connected to the electrode layers of the optical component 60.

The optical component 60 includes, but not limited to, a light emitter or an imaging sensor. In at least one embodiment, the optical component 60 is a light emitter, such as, a vertical cavity surface emitting laser (VCSEL), an edge emitting laser (EEL), a solid-state laser or a fiber laser, so that the packaging structure 100 is a transmitter equipment. At this time, when the electrodes 52 are connected to a power supply, a light emitting layer of the optical component 60 is excited to emit light, so as to generate laser light. A light emitting surface of the optical component 60 faces the optical lens assembly 40, so that the laser light generated by the optical component 60 passes through the optical lens assembly 40 to generate a converging beam or a diverging beam.

In at least one embodiment, a receiving groove 103 may be recessed from the second surface 102 to the first surface 101. The packaging structure 100 may further include a first adhesive layer 70. The first adhesive layer 70 may be made of epoxy glue or vinyl glue. The first adhesive layer 70 is received in the receiving groove 103 and connects the support 20 and the first transparent substrate 10, so that the support 20 is prevented from sliding on the first transparent substrate 10, and a distance between the optical component 60 and the optical lens assembly 40 can be adjusted, thereby the light source quality or imaging quality of the packaging structure 100.

In at least one embodiment, the first transparent substrate 10 may be provided without the receiving groove 103, and the packaging structure 100 may be provided without the first adhesive layer 70, the support 20 may be directly fixed on the first transparent substrate 10.

In the illustrated embodiment, the support 20 may be directly fixed on the third surface 301. In at least one embodiment, the support 20 may be connected to the second transparent substrate 30 through an adhesive layer.

In the illustrated embodiment, only one optical lens assembly 40 is received in the first cavity 201, and only one optical component 60 is received in the second cavity 202. In at least one embodiment, a plurality of optical lens assembles 40 may be received in the first cavity 201, and a plurality of optical components 60 may be received in the second cavity 202.

In at least one embodiment, when the distance R between the optical component 60 and the optical lens assembly 40 is greater than or equal to 3 μm, a half angle of the laser beam emitted by the packaging structure 100 is less than or equal to 2.9°.

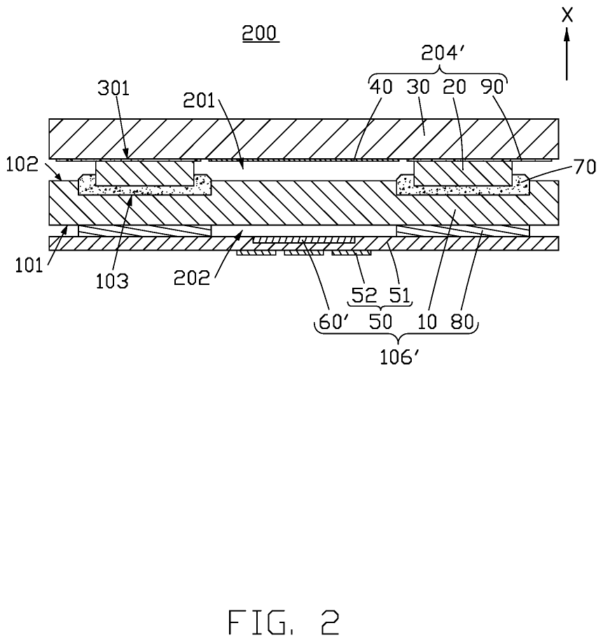

FIG. 2 illustrates a second embodiment of a packaging structure 200. The packaging structure 200 is different from the packaging structure 100 of the first embodiment in that the optical component 60′ is an imaging sensor, so that the packaging structure 100 is a receiving equipment. A light receiving surface of the optical component 60′ faces the optical lens assembly 40, so that the light passing through the optical lens assembly 40 is projected to the optical component 60′ for imaging. The imaging sensor may include a photoelectric conversion assembly (not shown), a filter (not shown) and a microlens assembly (not shown) stacked in sequence. The microlens assembly is closer to the first surface 101 than the filter. The photoelectric conversion assembly is electrically connected to the electrodes 52. The photoelectric conversion assembly may be a charge-coupled device (CCD). The optical component 60′ and the first surface 101 are arranged at intervals to prevent the optical component 60′ from being worn by the first transparent substrate 10.

In at least one embodiment, the packaging structure 200 may further include a second adhesive layer 80 connecting the first surface 101 and a surface of the base 51 facing away from the electrodes 52. The second adhesive layer 80 is located outside an overlapping area of the optical component 60′ and the optical lens assembly 40.

In at least one embodiment, the packaging structure 200 may further include a light blocking member 90 connecting the third surface 301 and a surface of the support 20 facing away from the first transparent substrate 10. The light blocking member 90 is arranged around an outer periphery of the optical lens assembly 40 for blocking light for the optical lens assembly 40. The light blocking member 90 may be made of metal or opaque polymer. The light blocking member 90 can prevent the incident light from a side of the support 20 facing away from the first cavity 201 from affecting the imaging quality of the imaging sensor. At the same time, the light blocking member 90 is beneficial to relax the material selection of the support 20, so that the support 20 may be made of a transparent material.

In at least one embodiment, the light blocking member 90 may be omitted.

The optical lens assembly 40 is received in the first cavity 201 defined by the first transparent substrate 10, the support 20, and the second transparent substrate 30 to be packaged and protected. The optical component 60′ is received in the second cavity 202 defined by the base 51 and the first transparent substrate 10 to be packaged and protected. As a result, the optical component 60′ and the optical lens assembly 40 can be prevented from being scratched by external force, and the yield and service life of the packaging structure 100 and the packaging structure 200 can be improved.

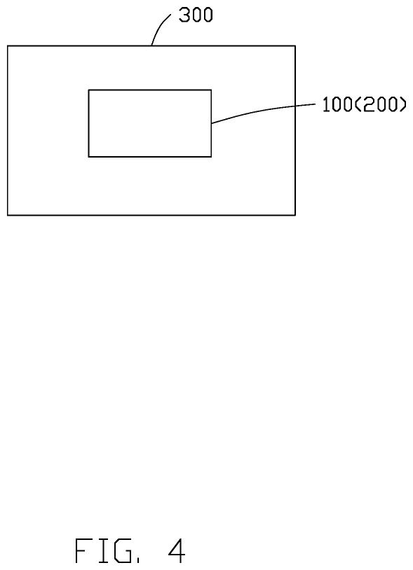

FIG. 4 illustrates an embodiment of an electronic device 300 including the above packaging structure 100 or 200. The electronic device 300 may be, but not limited to, an inspection equipment.

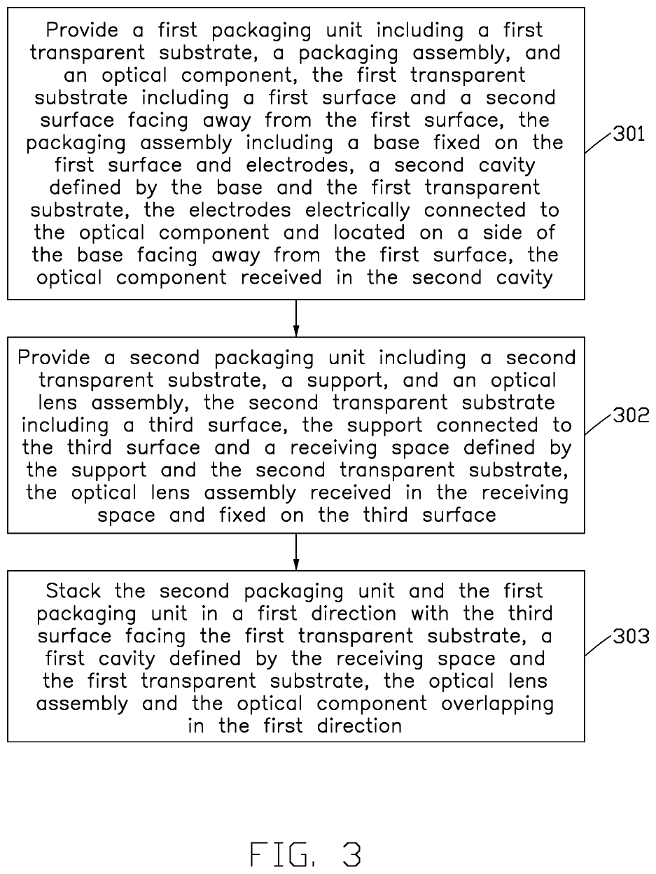

FIG. 3 illustrates a flowchart of a method in accordance with an embodiment. The embodiment method for manufacturing a packaging structure 100 (shown in FIG. 1) is provided by way of embodiments, as there are a variety of ways to carry out the method. Each block shown in FIG. 3 represents one or more processes, methods, or subroutines carried out in the method. Furthermore, the illustrated order of blocks can be changed. Additional blocks may be added or fewer blocks may be utilized, without departing from this disclosure. The method can begin at block 301.

At block 301, referring to FIG. 1 and FIG. 3, a first packaging unit 106 is provided. The first packaging unit 106 includes a first transparent substrate 10, a packaging assembly 50, and an optical component 60.

The first transparent substrate 10 includes a first surface 101 and a second surface 102 facing away from the first surface 101. The packaging assembly 50 includes a base 51 and electrodes 52. The base 51 is fixed on the first surface 101. A second cavity 202 is defined by the base 51 and the first transparent substrate 10. The electrodes 52 are electrically connected to the optical component 60 and located on a side of the base 51 facing away from the first surface 101. The optical component 60 is received in the second cavity 202 and fixed on the first surface 101. The optical component 60 includes a light emitter or an imaging sensor. In at least one embodiment, the optical component 60 is a light emitter, such as, a vertical cavity surface emitting laser (VCSEL), an edge emitting laser (EEL), a solid-state laser or a fiber laser. The optical component 60 may be formed on the first surface 101 by metal organic chemical vapor deposition (MOCVD), impressing technology, photolithography technology, electron beam lithography technology or femtosecond laser direct writing technology. The base 51 may be connected to the first surface 101 by impressing technology.

In at least one embodiment, referring to FIG. 1, a receiving groove 103 may be recessed from the second surface 102 to the first surface 101.

At block 302, referring to FIG. 1 and FIG. 3, a second packaging unit 204 is provided. The second packaging unit 204 includes a second transparent substrate 30, a support 20, and an optical lens assembly 40.

The second transparent substrate 30 includes a third surface 301. The support 20 is connected to the third surface 301 and a receiving space (not labeled) is defined by the support 20 and the second transparent substrate 30. The support 20 fixed on the third surface 301 may be formed by impressing technology, etching technology, or metal organic chemical vapor deposition technology. The optical lens assembly 40 is received in the receiving space and fixed on the third surface 301. The optical lens assembly 40 may be, but not limited to, a Metalens. The optical lens assembly 40 fixed on the third surface 301 may be formed by photolithography, electron beam lithography (EBL), nanoimprint lithography (NIL) or femtosecond laser direct writing.

At block 303, the second packaging unit 204 is stacked on the first packaging unit 106 with the third surface 301 facing the first transparent substrate 10, and the support 20 is connected to the second surface 102, so that the first transparent substrate 10 and the second transparent substrate 30 are stacked in a first direction X. A first cavity 201 is defined by the receiving space and the first transparent substrate 10, and the optical lens assembly 40 is received in the first cavity 201. The optical lens assembly 40 and the optical component 60 may overlap in the first direction X.

In at least one embodiment, a first adhesive layer 70 is formed in the receiving groove 103 to connect the support 20 and the first transparent substrate 10, thereby obtaining the packaging structure 100.

In at least one embodiment, the receiving groove 103 may be omitted, and the support 20 and the first transparent substrate 10 may be fixed by impressing technology.

A second embodiment of a method for manufacturing a packaging structure 200 (shown in FIG. 2) is provided. The second embodiment is substantially similar to the first embodiment and includes the following steps. Some of the steps that are the same as in the first embodiment are not described for the brevity of description.

The optical component 60′ is an imaging sensor, the optical component 60′ and the first surface 101 are arranged at intervals. Specifically, a second adhesive layer 80 is formed to connect the first surface 101 and a surface of the base 51 facing away from the electrodes 52 and separates the first surface 101 from the base 51, and the second adhesive layer 80 is located outside an overlapping area of the optical component 60′ and the optical lens assembly 40.

In at least one embodiment, the optical component 60′ may contact the first surface 101.

In at least one embodiment, the second packaging unit 204′ further includes a light blocking member 90 connecting the third surface 301 and a surface of the support 20 facing the third surface 301. The light blocking member 90 is arranged around an outer periphery of the optical lens assembly 40 for blocking light for the optical lens assembly 40. The support 20, the light blocking member 90, and the optical lens assembly 40 may be fixed by impressing technology.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A packaging structure comprising:
a first transparent substrate comprising a first surface and a second surface facing away from the first surface;
a second transparent substrate, the second transparent substrate and the first transparent substrate stacked in a first direction, and the second transparent substrate comprising a third surface facing the second surface of the first transparent substrate;
a support connecting the second surface and the third surface, and a first cavity defined by the support connecting the second transparent substrate and the first transparent substrate;
an optical lens assembly received in the first cavity and fixed on the third surface;
a packaging assembly comprising a base fixed on the first surface and electrodes, a second cavity defined by the base and the first transparent substrate; and
an optical component received in the second cavity, wherein the optical component and the optical lens assembly overlaps in the first direction, the optical component is electrically connected to the electrodes and located between the first surface and the electrodes.

2. The packaging structure of claim 1, wherein a receiving groove is recessed from the second surface to the first surface, the packaging structure further comprises a first adhesive layer receiving the receiving groove, the first adhesive layer connects the support and the first transparent substrate.

3. The packaging structure of claim 1, wherein the optical component is fixed on the first surface.

4. The packaging structure of claim 3, wherein the optical component is a light emitter.

5. The packaging structure of claim 1, wherein the optical component is spaced from the first surface.

6. The packaging structure of claim 5, wherein the optical component is an imaging sensor, the packaging structure further comprises a second adhesive layer connecting the first surface and a surface of the base facing the first surface, the second adhesive layer is located outside an overlapping area of the optical component and the optical lens assembly.

7. The packaging structure of claim 1, wherein the packaging structure further comprises a light blocking member connecting the third surface and a surface of the support facing away from the first transparent substrate, the light blocking member is arranged around an outer periphery of the optical lens assembly.

8. The packaging structure of claim 1, wherein the electrodes are located in a surface of the base facing away from the first surface, the base is provided with conducting circuits, the electrodes are electrically connected to the optical component through the conducting circuits.

9. The packaging structure of claim 1, wherein the electrodes extend through the base to be connected to the optical component.

10. The packaging structure of claim 1, wherein a distance between the optical component and the optical lens assembly along the first direction is greater than or equal to 3 μm.

11. An electronic device comprising:
a packaging structure comprising:
a first transparent substrate comprising a first surface and a second surface facing away from the first surface;
a second transparent substrate, the second transparent substrate and the first transparent substrate stacked in a first direction, and the second transparent substrate comprising a third surface facing the second surface of the first transparent substrate;
a support connecting the second surface and the third surface, and a first cavity defined by the support connecting the second transparent substrate and the first transparent substrate;
an optical lens assembly received in the first cavity and fixed on the third surface;
a packaging assembly comprising a base fixed on the first surface and electrodes, a second cavity defined by the base and the first transparent substrate; and
an optical component received in the second cavity, wherein the optical component and the optical lens assembly overlaps in the first direction, the optical component is electrically connected to the electrodes and located between the first surface and the electrodes.

12. The electronic device of claim 11, wherein a receiving groove is recessed from the second surface to the first surface, the packaging structure further comprises a first adhesive layer receiving the receiving groove, the first adhesive layer connects the support and the first transparent substrate.

13. The electronic device of claim 11, wherein the optical component is fixed on the first surface.

14. The electronic device of claim 13, wherein the optical component is a light emitter.

15. The electronic device of claim 11, wherein the optical component is spaced from the first surface.

16. The electronic device of claim 15, wherein the optical component is an imaging sensor, the packaging structure further comprises a second adhesive layer connecting the first surface and a surface of the base facing the first surface, the second adhesive layer is located outside an overlapping area of the optical component and the optical lens assembly.

17. The electronic device of claim 11, wherein the packaging structure further comprises a light blocking member connecting the third surface and a surface of the support facing away from the first transparent substrate, the light blocking member is arranged around an outer periphery of the optical lens assembly.

18. The electronic device of claim 11, wherein the electrodes are located in a surface of the base facing away from the first surface, the base is provided with conducting circuits, the electrodes are electrically connected to the optical component through the conducting circuits.

19. The electronic device of claim 11, wherein the electrodes extend through the base to be connected to the optical component.

20. The electronic device of claim 11, wherein a distance between the optical component and the optical lens assembly along the first direction is greater than or equal to 3 μm.
